(19) United States
(12) Patent Application Publication
(10) Pub. No.: US 2021/0074621 A1
(43) Pub. Date: Mar. 11, 2021

(54) SEMICONDUCTOR PACKAGE

(71) Applicant: AMAZING MICROELECTRONIC CORP., NEW TAIPEI CITY (TW)

(72) Inventors: ZI-PING CHEN, NEW TAIPEI CITY (TW); KUN-HSIEN LIN, HSINCHU CITY (TW); CHE-HAO CHUANG, HSINCHU COUNTY (TW); YIMING TSENG, ZHUBEI CITY (TW)

(21) Appl. No.: 16/565,874

(22) Filed: Sep. 10, 2019

(51) Int. Cl. H01L 23/498; H01L 23/62; H01L 23/00; H01L 23/31; H01L 23/29

(52) U.S. Cl. CPC H01L 23/49838; H01L 23/62; H01L 24/48; H01L 23/49822; H01L 23/3121; H01L 23/293; H01L 2224/73265; H01L 24/73; H01L 2224/32225; H01L 2224/48225; H01L 2224/48091; H01L 2224/48106; H01L 24/32

(57) ABSTRACT

A semiconductor package includes an interconnect substrate, an insulating adhesive, a transient voltage suppressor (TVS) chip, at least one first conductive wire, and at least one second conductive wire. The interconnect substrate includes a bottom layer and a top layer, the bottom layer includes two first conductive blocks and a first insulating block therebetween, the top layer includes two second conductive blocks and a second insulating block therebetween, the second conductive blocks are respectively formed on the first conductive blocks, and the second insulating block is formed on the first insulating block. The insulating adhesive is formed on the second insulating block. The TVS chip is formed on the insulating adhesive without overlapping the second conductive blocks. The first conductive wire and the second conductive wire are respectively electrically connected to the second conductive blocks and electrically connected to the TVS chip.

### BACKGROUND OF THE INVENTION

### Field of the Invention

The present invention relates to a package structure, particularly to a semiconductor package.

### Description of the Related Art

Because the IC device sizes have been shrunk to nanometer scale, the consumer electronics, like the laptop and mobile devices, have been designed to be much smaller than ever. Without suitable protection devices, the functions of these electronics could be reset or even damaged under ESD (Electrostatic Discharge) events. Currently, all consumer electronics are expected to pass the ESD test requirement of IEC 61000-4-2 standard. TVS (Transient Voltage Suppressor) is generally designed to bypass the ESD energy, so that the electronic systems can be prevented from ESD damages.

In order to save the areas of printed circuit boards (PCBs), semiconductor packages, such as packages DFN1006 or DFN0603, are designed to be minimization as much as possible. Conventionally, many TVS chips are encapsulated in chip on lead (COL) packages to achieve minimization. As shown in FIG. 1, the COL package includes two lead frames 10, an insulating adhesive 12, a TVS chip 14, and two bonding wires 16. The TVS chip 14 is formed on the lead frames 10 through the insulating adhesive 12 and electrically connected to the lead frames 10 through the bonding wires 16. The TVS chip 14 itself has a parasitic capacitance C_{chip}. The lead frames 10 form a parasitic capacitance C_{LF}. The TVS chip 14 and the lead frames 10 form two parasitic capacitances C_{OL}. Thus, the total capacitance of the COL package is represented by Cₜₒₜₐₗ=C_{chip}+C_{LF}+C_{OL}×C_{OL}/(C_{OL}+C_{OL}). That is to say, the capacitance of the packaged TVS chip 14 is greatly larger than the capacitance of the TVS chip 14.

To overcome the abovementioned problems, the present invention provides a semiconductor package, so as to solve the afore-mentioned problems of the prior art.

### SUMMARY OF THE INVENTION

The primary objective of the present invention is to provide a semiconductor package, which increases a distance between a transient voltage suppressor (TVS) chip and the conductive portions of an interconnect substrate to greatly reduce the parasitic capacitances formed by the TVS chip and the interconnect substrate.

To achieve the abovementioned objectives, the present invention provides a semiconductor package, which comprises an interconnect substrate, an insulating adhesive, a transient voltage suppressor (TVS) chip, at least one first conductive wire, and at least one second conductive wire. The interconnect substrate includes a bottom layer and a top layer, the bottom layer includes two first conductive blocks and a first insulating block therebetween, the top layer includes two second conductive blocks and a second insulating block therebetween, the second conductive blocks are respectively formed on the first conductive blocks, and the second insulating block is formed on the first insulating block. The insulating adhesive is formed on the second insulating block. The TVS chip is formed on the insulating adhesive without overlapping the second conductive blocks. The first conductive wire and the second conductive wire are respectively electrically connected to the second conductive blocks and electrically connected to the TVS chip.

In an embodiment of the present invention, the width of the first insulating block is shorter than the width of the second insulating block, and the TVS chip overlaps a part of each of the first conductive blocks.

In an embodiment of the present invention, the interconnect substrate further comprises at least one middle layer formed between the top layer and the bottom layer, the at least one middle layer comprises two third conductive blocks and a third insulating block therebetween, the width of the first insulating block is shorter than the width of the third insulating block, the third conductive blocks are respectively formed on the first conductive blocks, the second conductive blocks are respectively formed on the third conductive blocks, the third insulating block is formed on the first conductive blocks and the first insulating block, the second insulating block is formed on the third insulating block, and the TVS chip is formed over the third insulating block without overlapping the third conductive blocks.

In an embodiment of the present invention, the width of the third insulating block is larger than the width of the second insulating block.

In an embodiment of the present invention, the insulating adhesive overlaps the part of each of the first conductive blocks without overlapping the second conductive blocks and the third conductive blocks.

In an embodiment of the present invention, the first insulating block, the second insulating block, and the third insulating block comprise insulating compound.

In an embodiment of the present invention, the interconnect substrate is a molded interconnect substrate.

In an embodiment of the present invention, the semiconductor package further comprises a packaging adhesive encapsulating the TVS chip, the at least one first conductive wire, and the at least one second conductive wire.

In an embodiment of the present invention, the packaging adhesive comprises silicone or epoxy resin.

In an embodiment of the present invention, the at least one first conductive wire and the at least one second conductive wire comprise aluminum, copper, gold, or silver.

Below, the embodiments are described in detail in cooperation with the drawings to make easily understood the technical contents, characteristics and accomplishments of the present invention.

### BRIEF DESCRIPTION OF THE DRAWINGS

FIG. 1 is a schematic diagram illustrating a chip on lead (COL) package in the conventional technology;

FIG. 2 is a cross-sectional view of a semiconductor package according to the first embodiment of the present invention; and

FIG. 3 is a cross-sectional view of a semiconductor package according to the second embodiment of the present invention.

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

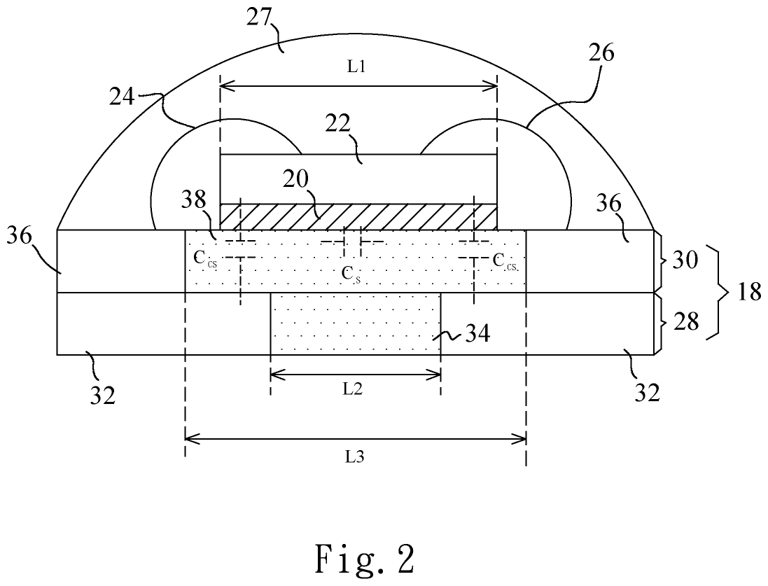

Refer to FIG. 2. The first embodiment of the semiconductor package of the present invention is introduced as follows. The semiconductor package is a chip on lead (COL) package, which comprises an interconnect substrate 18, an insulating adhesive 20, a transient voltage suppressor (TVS) chip 22, at least one first conductive wire 24, at least one second conductive wire 26, and a packaging adhesive 27. For example, the packaging adhesive 27 comprises silicone or epoxy resin. The first conductive wire 24 and the second conductive wire 26 comprise aluminum, copper, gold, or silver. In an embodiment of the present invention, the interconnect substrate 18 is a molded interconnect substrate having an area of 1 mm×0.3˜0.6 mm due to the size of the COL package.

The interconnect substrate 18 includes a bottom layer 28 and a top layer 30. The bottom layer 28 includes two first conductive blocks 32 and a first insulating block 34 therebetween. The first insulating block 34 is arranged between the first conductive blocks 32. The top layer 30 includes two second conductive blocks 36 and a second insulating block 38 therebetween. The second insulating block 38 is arranged between the second conductive blocks 36. The first insulating block 34 and the second insulating block 38 comprise insulating compound. The second conductive blocks 36 are respectively formed on the first conductive blocks 32. The second insulating block 38 is formed on the first insulating block 34. The insulating adhesive 20 is formed on the second insulating block 38. The TVS chip 22 has a width L1. The width L1 of the TVS chip 22 is larger than the width L2 of the first insulating block 34 and less than the width L3 of the second insulating block 38.

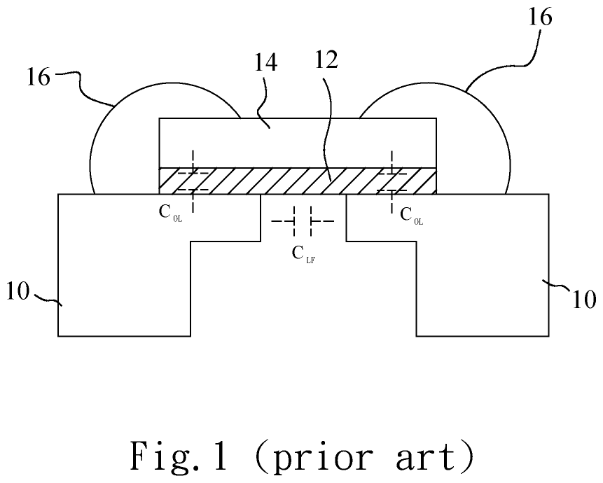

The TVS chip 22 is formed on the insulating adhesive 20 without overlapping the second conductive blocks 36. The first conductive wire 24 and the second conductive wire 26 are respectively electrically connected to the second conductive blocks 36 and electrically connected to the TVS chip 22. The packaging adhesive 27 encapsulates the TVS chip 22, the first conductive wire 24, and the second conductive wire 26. In addition, limited by the external size of the COL package, the width L2 of the first insulating block 34 is shorter than the width L3 of the second insulating block 38. The TVS chip 22 overlaps a part of each of the first conductive blocks 32. Since the size of the insulating adhesive 20 is equal to the size of the TVS chip 22, the insulating adhesive 20 overlaps the part of each of the first conductive blocks 32 without overlapping the second conductive blocks 36. The second conductive blocks 36 form a parasitic capacitance C_{S}. The TVS chip 22 and the first conductive blocks 32 form two parasitic capacitances C_{CS}. Compared with FIG. 1, the width L3 of the second insulating block 38 is increased. Thus, the parasitic capacitance C_{S} is smaller than the parasitic capacitance C_{LF} of FIG. 1. Besides, a distance between the TVS chip 22 and the top layer 30 is less than a distance between the TVS chip 22 and the bottom layer 28. Thus, the parasitic capacitance C_{CS} is smaller than the parasitic capacitance C_{OL} of FIG. 1. Due to the reduced capacitances C_{S} and C_{CS}, the total capacitance of the semiconductor package is closer to the parasitic capacitance of the TVS chip 22.

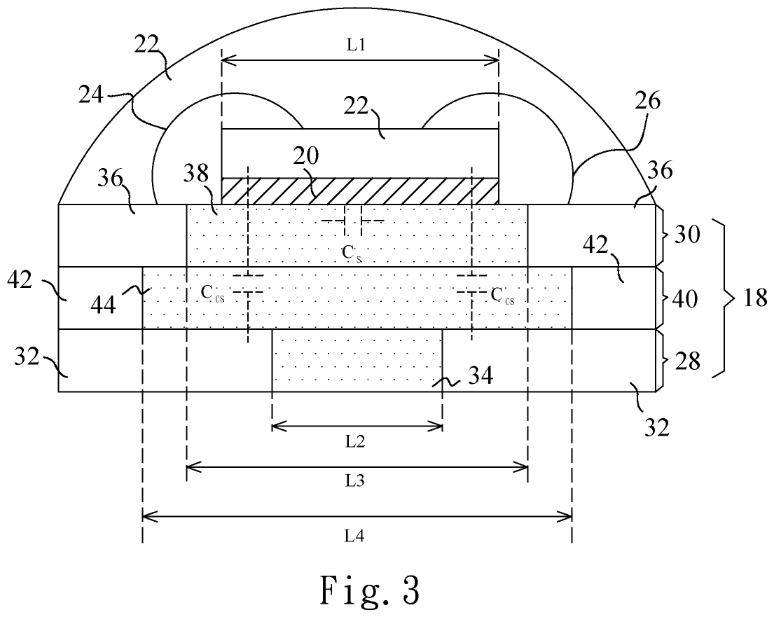

Refer to FIG. 3. The second embodiment of the semiconductor package of the present invention is introduced as follows. Compared with the first embodiment, the interconnect substrate 18 of the second embodiment further comprises at least one middle layer 40 formed between the top layer 28 and the bottom layer 30. The middle layer 40 comprises two third conductive blocks 42 and a third insulating block 44 therebetween, wherein the third insulating block 44 comprises insulating compound. The width L2 of the first insulating block 34 is shorter than the width L4 of the third insulating block 44. The third conductive blocks 42 are respectively formed on the first conductive blocks 32, the second conductive blocks 36 are respectively formed on the third conductive blocks 42, the third insulating block 44 is formed on the first conductive blocks 32 and the first insulating block 34, the second insulating block 38 is formed on the third insulating block 44, and the TVS chip 22 and the insulating adhesive 20 are formed over the third insulating block 44 without overlapping the third conductive blocks 42. Besides, the width L4 of the third insulating block 44 is larger than the width L3 of the second insulating block 38. Compared with the first embodiment, the middle layer 40 increases the distance between the TVS chip 22 and each of the first conductive blocks 32, so as to reduce the parasitic capacitances C_{CS} and the total capacitance of the semiconductor package.

In conclusion, the present invention increases a distance between the TVS chip and the conductive portions of the interconnect substrate to greatly reduce the parasitic capacitances formed by the TVS chip and the interconnect substrate.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A semiconductor package comprising:
an interconnect substrate comprising a bottom layer and a top layer, the bottom layer comprises two first conductive blocks and a first insulating block therebetween, the top layer comprises two second conductive blocks and a second insulating block therebetween, the second conductive blocks are respectively formed on the first conductive blocks, and the second insulating block is formed on the first insulating block;
an insulating adhesive formed on the second insulating block;
a transient voltage suppressor (TVS) chip formed on the insulating adhesive without overlapping the second conductive blocks; and
at least one first conductive wire and at least one second conductive wire respectively electrically connected to the second conductive blocks and electrically connected to the TVS chip.

2. The semiconductor package according to claim 1, wherein a width of the first insulating block is shorter than a width of the second insulating block, and the TVS chip overlaps a part of each of the first conductive blocks.

3. The semiconductor package according to claim 1, wherein the interconnect substrate further comprises at least one middle layer formed between the top layer and the bottom layer, the at least one middle layer comprises two third conductive blocks and a third insulating block therebetween, the width of the first insulating block is shorter than a width of the third insulating block, the third conductive blocks are respectively formed on the first conductive blocks, the second conductive blocks are respectively formed on the third conductive blocks, the third insulating block is formed on the first conductive blocks and the first insulating block, the second insulating block is formed on the third insulating block, and the TVS chip is formed over the third insulating block without overlapping the third conductive blocks.

4. The semiconductor package according to claim 3, wherein the width of the third insulating block is larger than the width of the second insulating block.

5. The semiconductor package according to claim 3, wherein the insulating adhesive overlaps a part of each of the first conductive blocks without overlapping the second conductive blocks and the third conductive blocks.

6. The semiconductor package according to claim 3, wherein the first insulating block, the second insulating block, and the third insulating block comprise insulating compound.

7. The semiconductor package according to claim 1, wherein the interconnect substrate is a molded interconnect substrate.

8. The semiconductor package according to claim 1, further comprising a packaging adhesive encapsulating the TVS chip, the at least one first conductive wire, and the at least one second conductive wire.

9. The semiconductor package according to claim 8, wherein the packaging adhesive comprises silicone or epoxy resin.

10. The semiconductor package according to claim 1, wherein the at least one first conductive wire and the at least one second conductive wire comprise aluminum, gold, copper, or silver.
